(19) United States
(12) Patent Application Publication
(10) Pub. No.: US 2025/0374493 A1
(43) Pub. Date: Dec. 4, 2025

(54) HEAT RADIATION DEVICE

(71) Applicant: Samsung Display Co., LTD., Yongin-si (KR)

(72) Inventors: Cheul Jin PARK, Yongin-si (KR); Ju Hee KIM, Yongin-si (KR); Eun Won SEO, Yongin-si (KR); Jun Hee SON, Yongin-si (KR)

(21) Appl. No.: 19/037,846

(22) Filed: Jan. 27, 2025

(30) Foreign Application Priority Data
Jun. 4, 2024 (KR) 10-2024-0072959

(51) Int. Cl. H05K 7/20; G06F 1/20

(52) U.S. Cl. CPC H05K 7/20981; G06F 1/20

(57) ABSTRACT

A heat radiation device includes a core plate, a first flow path in which one surface of the core plate is recessed in the thickness direction of the core plate to form a path in which refrigerant flows through, a second flow path in which the other surface opposite to the one surface of the core plate is recessed in the thickness direction of the core plate to form a path in which the refrigerant flows through, and a connection portion connecting the first flow path and the second flow path.

### CROSS-REFERENCE TO RELATED APPLICATION

The present application claims priority to and the benefit of Korean Patent Application No. 10-2024-0072959, filed on Jun. 4, 2024, in the Korean Intellectual Property Office, the entire content of which is hereby incorporated by reference.

### BACKGROUND

### 1. Field

Embodiments of the present disclosure relate to a heat radiation device.

### 2. Description of the Related Art

Generally, electronic devices such as smartphones, tablet PCs, digital cameras, laptop computers, navigation systems, and smart TVs include display devices that display images.

A display device may include a plurality of light emitting elements, and the plurality of light emitting elements may display images through power applied from the outside (e.g., from outside the light emitting elements). Among the power applied to the plurality of light emitting elements, a portion of the power that is not converted into light energy may be accumulated in the display device in the form of heat energy.

Heat accumulated in a display device is one of the main causes of deteriorating the display quality of the display device.

Heat accumulated in the display device may be emitted to the outside of the display device by a heat radiation device in contact with the display device.

### SUMMARY

Aspects of embodiments of the present disclosure provide a heat radiation device capable of increasing the heat diffusion efficiency of one side and an other side of the heat radiation device without increasing the overall thickness of the heat radiation device.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an aspect of embodiments of the present disclosure, a heat radiation device includes a core plate, a first flow path in which one surface of the core plate is recessed in a thickness direction of the core plate to form a path in which a refrigerant flows through, a second flow path in which the other surface opposite to the one surface of the core plate is recessed in the thickness direction of the core plate to form a path in which the refrigerant flows through, and a connection portion connecting the first flow path and the second flow path.

The first flow path and the second flow path may be extended in a same one direction.

The connection portion is provided in plural numbers (e.g., as a plurality of connection portions), the plurality of connection portions include a first connection portion and a second connection portion, the first connection portion is on one end of the one direction of the core plate, and the second connection portion is on an other end of the one direction of the core plate.

The first flow path and the second flow path are provided in plural numbers (e.g., as a plurality of first flow paths and a plurality of second flow paths), and the plurality of first flow paths and the plurality of second flow paths are alternately provided.

Extended ends on both sides (e.g., on two opposing sides) of the first flow path and the second flow path are open, and a first side block blocking one extended end among the extended ends on both sides (e.g., on two opposing sides) of the first flow path and the second flow path, and a second side block blocking an other extended end among extended ends on both sides (e.g., on two opposing sides) of the first flow path and the second flow path.

A third flow path may be provided in any one of the first side block and the second side block and connect the first flow path and the second flow path.

The cross-sectional area of the third flow path may be smaller than the cross-sectional area of the first flow path and the cross-sectional area of the second flow path.

A first cover plate may be on one surface of the core plate to block the first flow path, and a second cover plate may be on the other surface of the core plate to block the second flow path.

The connection portion may be an area where a portion of the core plate between the first flow path and the second flow path is removed.

The cross-sectional area of the connection portion may be larger than the cross-sectional area of the first flow path and smaller than the cross-sectional area of the second flow path.

The cross-sectional area of the first flow path may be smaller than the cross-sectional area of the second flow path.

The first connection portion may extend from the one end of the one direction of the core plate to the other end of the one direction of the core plate, and the second connection portion may extend from the other end of the one direction of the core plate to the one end of the one direction of the core plate.

The connection portion may be provided as a plurality of holes penetrating the core plate between the first flow path and the second flow path.

The plurality of holes may be provided in the thickness direction of the core plate and the one direction.

At least one or more among the plurality of holes have a diameter different from a diameter of another hole among the plurality of holes.

A diameter of each of the holes provided at a central portion among the plurality of holes is larger than a diameter of each of the holes provided at a peripheral portion among the plurality of holes.

A guide portion may extend from the connection portion to a flow direction of a refrigerant.

The guide portion may be provided in plural numbers (e.g., as a plurality of guide portions), the plurality of guide portions may each include a first guide portion and a second guide portion, the first guide portion may extend from the first connection portion, and the second guide portion may extend from the second connection portion.

The first guide portion may extend from the first connection portion toward the second flow path, and the second guide portion may extend from the second connection portion toward the first flow path.

The first guide portion may extend toward the one end of the one direction of the core plate, and the second guide portion may extend toward the other end of the one direction of the core plate.

In the heat radiation device according to embodiments of the present disclosure, there is an effect of increasing the heat diffusion efficiency of one side and an other side of the heat radiation device without increasing an overall thickness of the heat radiation device by providing a first flow path and a second flow path that communicate with each other on the one side and the other side of a core plate.

In some embodiments of the heat radiation device of the present disclosure, there is an effect of preventing a refrigerant flowing in the first flow path and the second flow path from flowing in a reverse direction (or by reducing a reverse flow of the refrigerant flowing in the first flow path and the second flow path) by providing a guide portion at a connection portion connecting the first flow path and the second flow path.

In embodiments of the heat radiation device of the present disclosure, there is an effect of preventing or reducing damage to the heat radiation device if (e.g., when) reducing the bending rigidity of the heat radiation device to attach the heat radiation device to the display device by bending the core plate a plurality of times to form the first flow path and the second flow path.

Effects according to embodiments of the present disclosure are not limited to those mentioned above and more various suitable effects are included in the following description of the present disclosure.

### BRIEF DESCRIPTION OF THE DRAWINGS

The above and other aspects and features of embodiments of the present disclosure will become more apparent by describing in more detail example embodiments thereof with reference to the attached drawings, in which:

FIG. 1 is a diagram illustrating a state in which a heat radiation device according to an embodiment of the present disclosure is in contact with a display device;

FIG. 2 is a perspective view illustrating a core plate of a heat radiation device according to an embodiment of the present disclosure;

FIG. 3 is a front view of the core plate of FIG. 2;

FIG. 4 is a cross-sectional view taken along line A-A′ of FIG. 2;

FIG. 5 is a cross-sectional view taken along line B-B′ of FIG. 2;

FIG. 6 is a diagram illustrating a flow of a refrigerant in a state where a first side block and a second side block are provided in the core plate of the heat radiation device according to an embodiment of the present disclosure;

FIG. 7 is an exploded perspective view of the heat radiation device according to an embodiment of the present disclosure;

FIG. 8 is a front cross-sectional view of the heat radiation device according to an embodiment of the present disclosure;

FIG. 9 is a perspective view illustrating a core plate of a heat radiation device according to an embodiment of the present disclosure;

FIG. 10 is a plan view of the core plate of FIG. 9;

FIG. 11 is a front view of the core plate of FIG. 9;

FIG. 12 is a cross-sectional view taken along line C-C′ of FIG. 9;

FIG. 13 is a cross-sectional view cut along line D-D′ of FIG. 9;

FIG. 14 is a front cross-sectional view of the heat radiation device according to an embodiment of the present disclosure;

FIG. 15 is a perspective view illustrating a core plate of a heat radiation device according to an embodiment of the present disclosure;

FIG. 16 is a cross-sectional view taken along line E-E′ of FIG. 15; and

FIG. 17 is a cross-sectional view taken along line F-F′ of FIG. 15.

### DETAILED DESCRIPTION

Features of embodiments of the present disclosure and methods to achieve them will become apparent from the descriptions of example embodiments hereinbelow with reference to the accompanying drawings. However, the present disclosure is not limited to the example embodiments disclosed herein but may be implemented in various suitable different ways. The example embodiments are provided for making the disclosure of the present disclosure thorough and for fully conveying the scope of the present disclosure to those skilled in the art. It is to be noted that the scope of the present disclosure is defined only by the appended claims, and equivalents thereof.

As used herein, a phrase “an element A on an element B” refers to that the element A may be directly on the element B and/or the element A may be indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish between the elements such terms describe, these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various suitable interactions and operations are possible. Various example embodiments can be practiced individually or in combination.

Hereinafter, example embodiments of the present disclosure will be described in more detail with reference to the accompanying drawings.

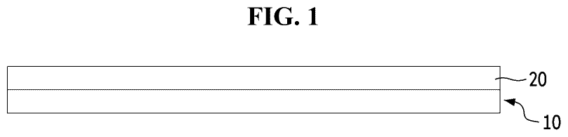

FIG. 1 is a diagram illustrating a state in which a heat radiation device 10 according to an embodiment of the present disclosure is in contact with a display device 20.

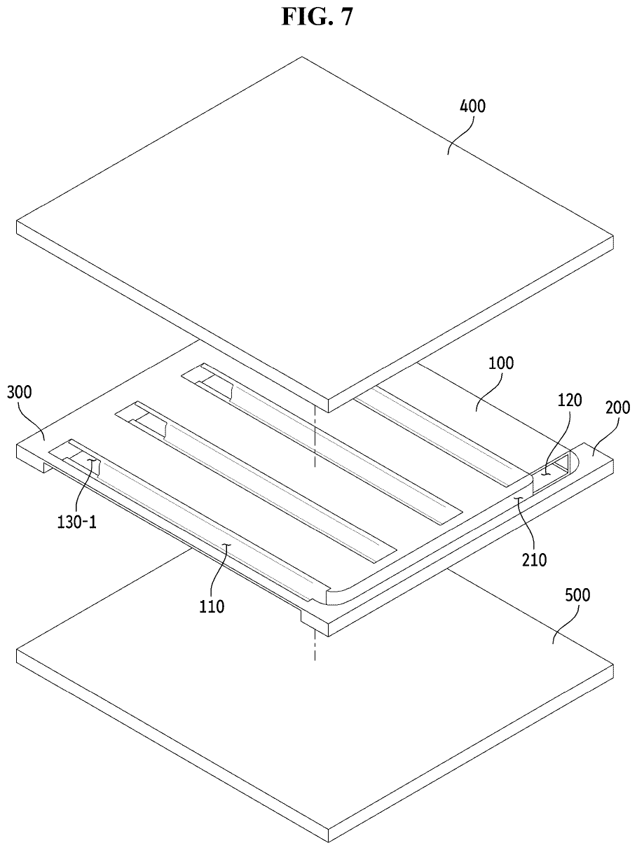

Referring to FIG. 1, the heat radiation device 10 according to an embodiment of the present disclosure may be provided to contact one surface of the display device 20 to emit heat generated in the display device 20 to the outside of the display device 20. Referring to FIG. 7, the heat radiation device 10 may include a core plate 100, a first side block 200, a second side block 300, a first cover plate 400, and a second cover plate 500.

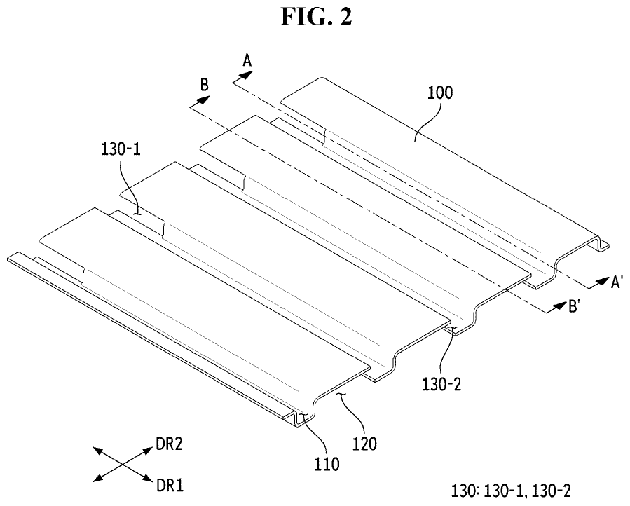

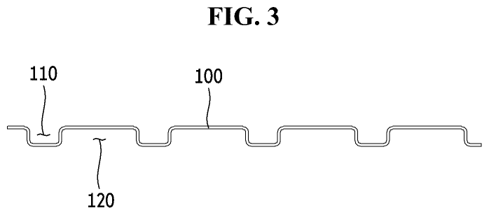

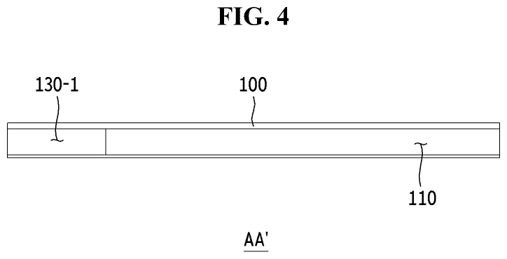

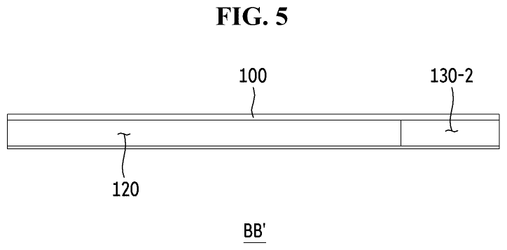

FIG. 2 is a perspective view illustrating the core plate 100 of a heat radiation device 10 according to an embodiment of the present disclosure. FIG. 3 is a front view of the core plate 100 of FIG. 2. FIG. 4 is a cross-sectional view taken along line A-A′ of FIG. 2. FIG. 5 is a cross-sectional view taken along line B-B′ of FIG. 2.

Referring to FIGS. 2-5, the core plate 100 may be provided as a plate having a set or predetermined thickness. The core plate 100 may be provided as a substantially square-shaped plate extending in a first direction DR1 and a second direction DR2 of FIG. 2, but the present disclosure is not limited thereto. The core plate 100 may be bent a plurality of times in the second direction DR2 to form a first flow path 110 and a second flow path 120. The core plate 100 may include the first flow path 110, the second flow path 120, and a connection portion 130.

The first flow path 110 may be formed as one surface (e.g., a top surface of FIG. 2) of the core plate 100 is recessed toward a thickness direction of the core plate 100 (e.g., a direction perpendicular or substantially perpendicular to the first direction DR1 and the second direction DR2). In some embodiments, the first flow path 110 may be formed as the core plate 100 is bent a plurality of times in the second direction DR2 so that the top surface of the core plate 100 is recessed in the thickness direction of the core plate 100. The first flow path 110 may extend in the first direction DR1 from one surface of the core plate 100. Extended ends on both sides (e.g., two opposing sides) of the first flow path 110 may be open. In some embodiments, one end of the first flow path 110 in the first direction DR1 and the other end thereof in the first direction DR1 may be formed to be open. The first flow path 110 may provide a passage for the refrigerant to flow. The plurality of first flow paths 110 may be provided to be spaced apart from each other along the second direction DR2 on the one surface of the core plate 100.

The second flow path 120 may be formed as an other surface (lower surface of FIG. 2) of the core plate 100 is recessed in the thickness direction of the core plate 100. In some embodiments, the second flow path 120 may be formed as the core plate 100 is bent a plurality of times in the second direction DR2 so that the lower surface of the core plate 100 is recessed in the thickness direction of the core plate 100. The cross-sectional area of the second flow path 120 in the second direction DR2 may be formed to be larger than the cross-sectional area of the first flow path 110 in the second direction DR2. The second flow path 120 may extend in the first direction DR1 from the other surface of the core plate 100. Extended ends on both sides (e.g., two opposing sides) of the second flow path 120 may be open. In some embodiments, one end of the second flow path 120 in the first direction DR1 and the other end thereof in the first direction DR1 may be formed to be open. The second flow path 120 may provide a passage for the refrigerant to flow. The plurality of second flow paths 120 may be provided to be spaced apart from each other along the second direction DR2 on the other surface of the core plate 100. The second flow path 120 may be on the same virtual horizontal line as the first flow path 110. The second flow path 120 may be between the first flow paths 110. In some embodiments, the first flow paths 110 and the second flow paths 120 may be alternately provided.

The connection portion 130 may connect the first flow path 110 and the second flow path 120. The connection portion 130 may be an area where a portion of the core plate 100 between the first flow path 110 and the second flow path 120 is removed. In some embodiments, the connection portion 130 may connect the first flow path 110 and the second flow path 120 by removing a portion of the core plate 100. The refrigerant of the first flow path 110 may flow through the connection portion 130 to the second flow path 120. The cross-sectional area of the connection portion 130 in the first direction DR1 may be larger than the cross-sectional area of the first flow path 110 in the second direction DR2 and smaller than the cross-sectional area of the second flow path 120 in the second direction DR2. A plurality of connection portions 130 may be provided, and the plurality of connection portions 130 may include a first connection portion 130-1 and a second connection portion 130-2.

The first connection portion 130-1 may be formed by removing a portion of the core plate 100 between the first flow path 110 and the second flow path 120 adjacent in the second direction DR2. The first connection portion 130-1 may be connected to one end in the first direction DR1 of the core plate 100 between the first flow path 110 and the second flow path 120 adjacent in the second direction DR2. The first connection portion 130-1 may extend from the one end in the first direction DR1 to an other end in the first direction DR1 of the core plate 100 between the first flow path 110 and the second flow path 120 adjacent in the second direction DR2. In other words, the first connection portion 130-1 may be an area where the core plate 100 between the first flow path 110 and the second flow path 120 adjacent to the first flow path 110 is removed from the one end of the first direction DR1 to the other end of the first direction DR1.

The second connection portion 130-2 may be formed by removing a portion of the core plate 100 between the second flow path 120 and the first flow path 110 adjacent in the second direction DR2. The second connection portion 130-2 may be at the other end in the first direction DR1 of the core plate 100 between the second flow path 120 and the first flow path 110 adjacent in the second direction DR2. The second connection portion 130-2 may extend from the other end in the first direction DR1 to the one end in the first direction DR1 of the core plate 100 between the second flow path 120 and the first flow path 110 adjacent in the second direction DR2. In some embodiments, the second connection portion 130-2 may be an area where the core plate 100 between the second flow path 120 and the first flow path 110 adjacent to the second flow path 120 is removed from the other end of the first direction DR1 to the one end of the first direction DR1.

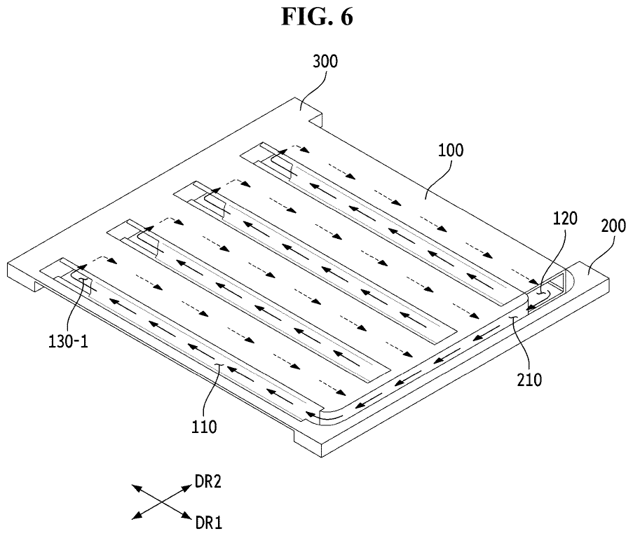

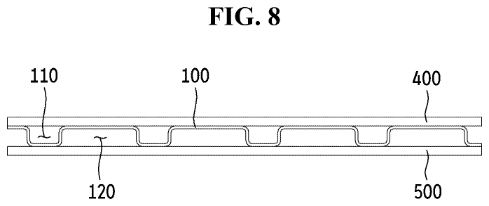

FIG. 6 is a diagram illustrating a flow of the refrigerant in a state where a first side block 200 and a second side block 300 are provided in a core plate 100 of the heat radiation device 10 according to an embodiment of the present disclosure. FIG. 7 is an exploded perspective view of the heat radiation device 10 according to an embodiment of the present disclosure. FIG. 8 is a front cross-sectional view of the heat radiation device 10 according to an embodiment of the present disclosure.

Referring to FIGS. 6-8, the first side block 200 may be coupled to the other end of the core plate 100 in the first direction DR1. The first side block 200 may be coupled to the other end of the core plate 100 in the first direction DR1 to block the other open end of the first flow path 110 and the second flow path 120. The first side block 200 may be coupled to the core plate 100 by an insert injection method. The first side block 200 may include a third flow path 210.

The third flow path 210 may connect the first flow path 110 and the second flow path 120. The third flow path 210 may be formed as the top surface of the first side block 200 is recessed in the thickness direction of the first side block 200. The third flow path 210 may connect the first flow path 110 provided on the leftmost side of the second direction DR2 of FIG. 6 and the second flow path 120 provided on the rightmost side of the second direction DR2 of FIG. 6. As described above, because the third flow path 210 connects the first flow path 110 provided on the leftmost side of the second direction DR2 of FIG. 6 and the second flow path 120 provided on the rightmost side of the second direction DR2 of FIG. 6, the refrigerant that flowed from the first flow path 110 and the second flow path 120 along arrows of FIG. 6 may flow from the second flow path 120 provided on the rightmost side of the second direction DR2 of FIG. 6 to the first flow path 110 provided on the leftmost side of the second direction DR2 of FIG. 6. The cross-sectional area of the third flow path 210 in the first direction DR1 may be formed to be smaller than the cross-sectional area of the first flow path 110 in the second direction DR2 and the cross-sectional area of the second flow path 120 in the second direction DR2.

The second side block 300 may be coupled to one end of the core plate 100 in the first direction DR1. The second side block 300 may be coupled to one end of the core plate 100 in the first direction DR1 and block one open end of the first flow path 110 and the second flow path 120 in the first direction DR1. The second side block 300 may be coupled to the core plate 100 by an insert injection method.

The first cover plate 400 may be provided as a plate having a set or predetermined thickness. The first cover plate 400 may be provided as a substantially square-shaped plate extending in the first direction DR1 and the second direction DR2, but the present disclosure is not limited thereto. The first cover plate 400 may be on one surface (e.g., a top surface of FIG. 7) of the core plate 100 to block the open top portion of the first flow path 110.

The second cover plate 500 may be provided as a plate having a set or predetermined thickness. The second cover plate 500 may be provided as a substantially square-shaped plate extending in the first direction DR1 and the second direction DR2, but the present disclosure is not limited thereto. The second cover plate 500 may have a same thickness and a same size as the first cover plate 400. The second cover plate 500 may be on an other surface (e.g., a lower surface of FIG. 7) of the core plate 100 to block the open lower portion of the second flow path 120.

Hereinafter, the operation and effect of a heat radiation device 10 according to an embodiment of the present disclosure will be described.

In the heat radiation device according to an embodiment of the present disclosure, because the first flow path 110 and the second flow path 120 in communication with each other on the one surface and the other surface of the core plate 100 are provided, but the first flow path 110 and the second flow path 120 are provided on a virtual horizontal line, there is an effect capable of increasing heat diffusion efficiency of the one surface and the other surface of the heat radiation device 10 while not increasing the overall thickness of the heat radiation device 10.

In the heat radiation device according to an embodiment of the present disclosure, because the core plate 100 is bent a plurality of times to form the first flow path 110 and the second flow path 120, there is an effect of preventing or reducing damage to the heat radiation device 10 if (e.g., when) reducing the bending rigidity of the heat radiation device 10 to attach the heat radiation device 10 to the display device 20.

A heat radiation device 10 according to other embodiments of the present disclosure may be provided. Another embodiment of the present invention will be described with reference to the drawings. Compared with the embodiment described above, other embodiments of the present disclosure may be different with respect to, for example, a guide portion 140, and thus, such difference will be mainly described, and the embodiment described above will be relied upon for the same description.

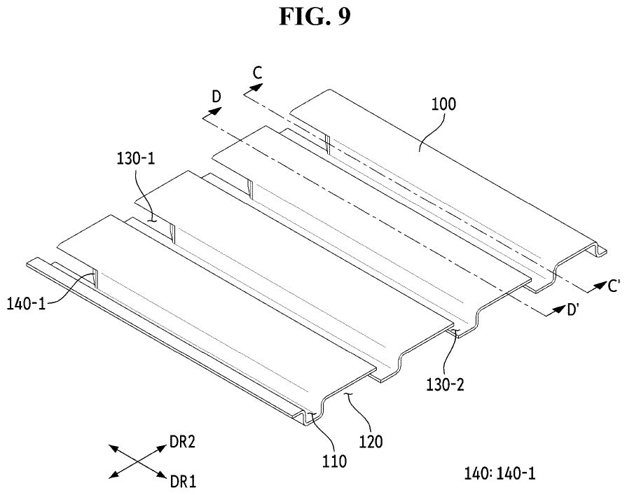

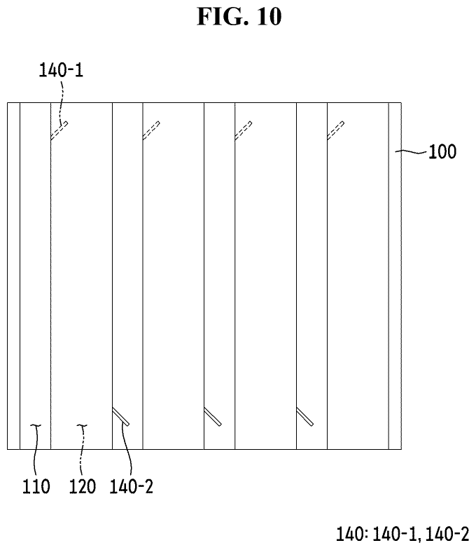

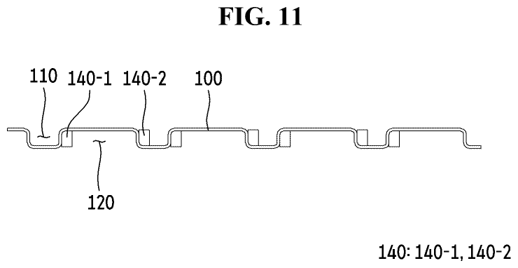

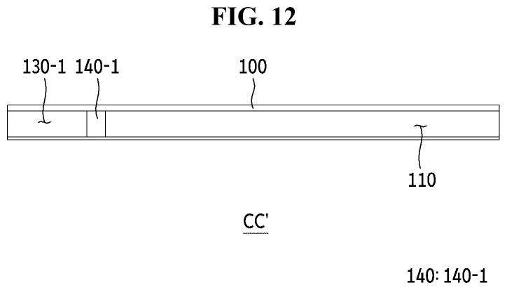

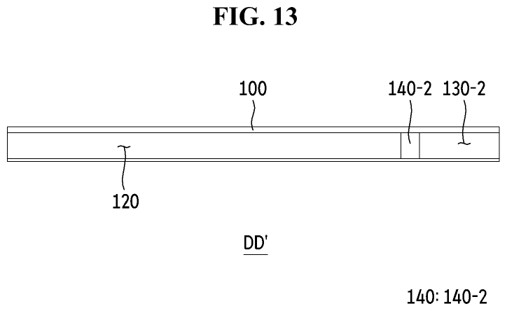

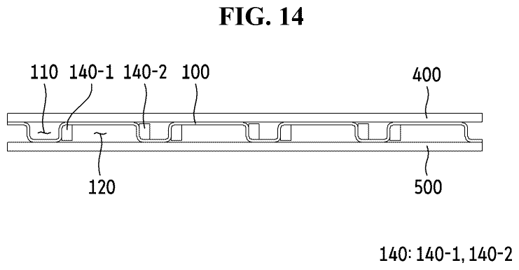

FIG. 9 is a perspective view illustrating a core plate 100 of a heat radiation device 10 according to an embodiment of the present disclosure. FIG. 10 is a plan view of the core plate 100 of FIG. 9. FIG. 11 is a front view of the core plate 100 of FIG. 9. FIG. 12 is a cross-sectional view taken along line C-C′ of FIG. 9. FIG. 13 is a cross-sectional view taken along line D-D′ of FIG. 9. FIG. 14 is a front cross-sectional view of the heat radiation device 10 according to an embodiment of the present disclosure.

Referring to FIGS. 9-14, the heat radiation device 10 according to an embodiment of the present disclosure may further include the guide portion 140.

The guide portion 140 may extend from the connection portion 130 to the flow direction of the refrigerant and prevent or reduce reverse flow of the refrigerant. A plurality of guide portions 140 may be provided, and the plurality of guide portions 140 may include a first guide portion 140-1 and a second guide portion 140-2.

The first guide portion 140-1 may extend from the first connection portion 130-1 to the flow direction of the refrigerant. The extension length of the first guide portion 140-1 may be formed to be shorter than a length of the first connection portion 130-1 in the first direction DR1. The first guide portion 140-1 may extend at an angle inclined from the other end of the first connection portion 130-1 in the first direction DR1 toward the second flow path 120. In some embodiments, the first guide portion 140-1 may extend from the other end of the first connection portion 130-1 in the first direction DR1 to a direction between the second direction DR2 where the second flow path 120 is provided and the one end direction of the core plate 100 in the first direction DR1.

The second guide portion 140-2 may extend from the second connection portion 130-2 to the flow direction of the refrigerant. The extension length of the second guide portion 140-2 may be formed to be shorter than a length of the second connection portion 130-2 in the first direction DR1. The second guide portion 140-2 may extend at an angle inclined from the one end of the second connection portion 130-2 in the first direction DR1 toward the first flow path 110. In some embodiments, the second guide portion 140-2 may extend from the one end of the second connection portion 130-2 in the first direction DR1 to a direction between the second direction DR2 where the first flow path 110 is provided and the other end direction of the core plate 100 in the first direction DR1.

Hereinafter, the operation and effect of a heat radiation device 10 according to an embodiment of the present disclosure will be described.

In the heat radiation device 10 according to an embodiment of the present disclosure, because the first guide portion 140-1 and the second guide portion 140-2 extending at an angle inclined in the flow direction of the refrigerant are provided in each of the first connection portion 130-1 and the second connection portion 130-2, there is an effect of preventing or reducing reverse flow of the refrigerant that flows in the first flow path 110 and the second flow path 120.

A heat radiation device 10 according to other embodiments of the present disclosure may be provided. Another embodiment of the present disclosure will be described with reference to the drawings. Compared with the embodiments described above, the other embodiments may be different with respect to, for example, the form of a first connection portion 130-1′ and a second connection portion 130-2′, and thus, such difference will be mainly described, and the embodiments described above will be relied upon for the same description.

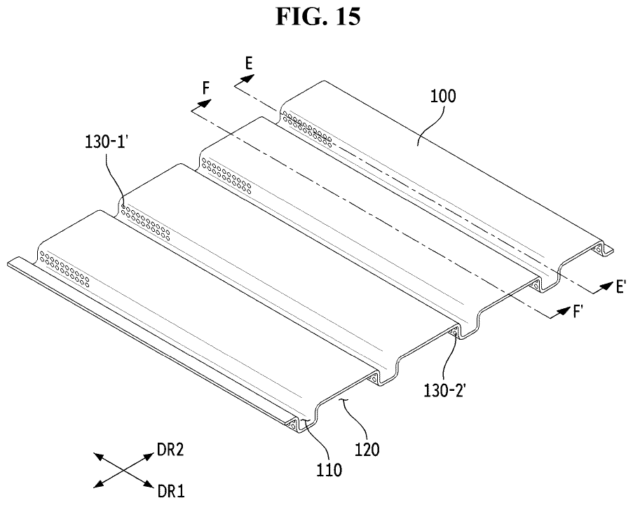

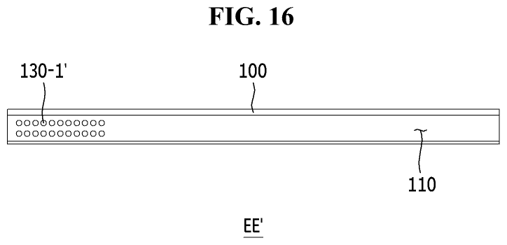

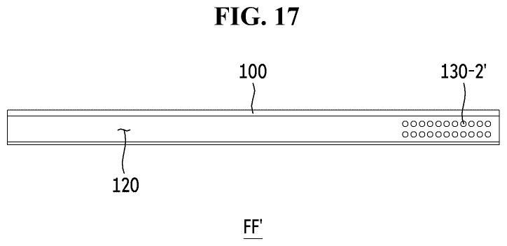

FIG. 15 is a perspective view illustrating a core plate 100 of a heat radiation device 10 according to an embodiment of the present disclosure. FIG. 16 is a cross-sectional view taken along line E-E′ of FIG. 15. FIG. 17 is a cross-sectional view taken along line F-F′ of FIG. 15.

Referring to FIGS. 15-17, the heat radiation device 10 according to an embodiment of the present disclosure may include the first connection portion 130-1′ and the second connection portion 130-2′.

The first connection portion 130-1′ may be provided as a plurality of holes penetrating the core plate 100 between the first flow path 110 and the second flow path 120 adjacent in the second direction DR2. The first connection portion 130-1′ may be connected at the one end of the first direction DR1 of the core plate 100 between the first flow path 110 and the second flow path 120 adjacent in the second direction DR2. The first connection portion 130-1′ may be formed as a plurality of holes provided from one end of the second direction DR2 of the core plate 100 between the first flow path 110 and the second flow path 120 adjacent to the first flow path 110 to the other end of the first direction DR1. In some embodiments, the first connection portion 130-1′ may be formed as the plurality of holes provided in the thickness direction of the core plate 100. At least one or more holes among the plurality of holes configuring the first connection portion 130-1′ may be formed to have a diameter different from a diameter of another of the plurality of holes. In some embodiments, a diameter of each of the holes provided at the central portion among the plurality of holes configuring the first connection portion 130-1′ may be formed to be greater than a diameter of each of the holes provided at the peripheral portion among the plurality of holes.

The second connection portion 130-2′ may be provided as a plurality of holes penetrating the core plate 100 between the second flow path 120 and the first flow path 110 adjacent in the second direction DR2. The second connection portion 130-2′ may be connected at the other end of the first direction DR1 of the core plate 100 between the second flow path 120 and the first flow path 110 adjacent in the second direction DR2. The second connection portion 130-2′ may be formed as a plurality of holes provided from the other end of the first direction DR1 of the core plate 100 between the second flow path 120 and the first flow path 110 adjacent in the second direction DR2 to the one end of the first direction DR1. In some embodiments, the second connection portion 130-2′ may be formed as the plurality of holes provided in the thickness direction of the core plate 100. At least one or more holes among the plurality of holes configuring the second connection portion 130-2′ may be formed to have a diameter different from a diameter of another hole of the plurality of holes. In some embodiments, a diameter of each of the holes provided at the central portion among the plurality of holes configuring the second connection portion 130-2′ may be formed to be greater than a diameter of each of the holes provided at the peripheral portion among the plurality of holes.

Hereinafter, the operation and effect of a heat radiation device 10 according to an embodiment of the present disclosure will be described.

While flowing through the first flow path 110 and the second flow path 120, the refrigerant may absorb heat from the display device 20 and be vaporized. A flow rate of the vaporized refrigerant may increase in the process where the vaporized refrigerant passes through the first connection portion 130-1′ and the second connection portion 130-2′, and the pressure of the refrigerant in the first connection portion 130-1′ and the second connection portion 130-2′ may decrease as the flow rate of the vaporized refrigerant increases, liquefying the vaporized refrigerant. Accordingly, because the liquefied refrigerant exists in the vicinity of the first connection portion 130-1′ and the second connection portion 130-2′, there is an effect of increasing the cooling efficiency of the display device 20 by absorbing heat generated in the display device 20 in the vicinity of the first connection portion 130-1′ and the second connection portion 130-2′.

An electronic device may include the heat radiation device according to embodiments of the present disclosure. The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

It should be understood, however, that the aspects and features of embodiments of the present disclosure are not restricted to the ones set forth herein. The above and other aspects of embodiments of the present disclosure will become more apparent to one of ordinary skill in the art to which the present disclosure pertains by referencing the claims, with equivalents thereof to be included therein.

What is claimed is:

1. A heat radiation device comprising:
a core plate;
a first flow path in which one surface of the core plate is recessed in a thickness direction of the core plate to form a path in which refrigerant flows through;
a second flow path in which an other surface opposite to the one surface of the core plate is recessed in the thickness direction of the core plate to form a path in which the refrigerant flows through; and
a connection portion connecting the first flow path and the second flow path.

2. The heat radiation device as claimed in claim 1,
wherein the first flow path and the second flow path are extended in a same one direction.

3. The heat radiation device as claimed in claim 2,
wherein the connection portion comprises a plurality of connection portions, the plurality of connection portions comprise a first connection portion and a second connection portion,
the first connection portion is provided at one end of the one direction of the core plate, and
the second connection portion is provided at an other end of the one direction of the core plate.

4. The heat radiation device as claimed in claim 2,
wherein the first flow path and the second flow path comprise a plurality of first flow paths and a plurality of second flow paths, and
the plurality of first flow paths and the plurality of second flow paths are alternately provided.

5. The heat radiation device as claimed in claim 2,
wherein extended ends at two opposing sides of the first flow path and the second flow path are open, and
a first side block blocking one extended end among the extended ends at the two opposing sides of the first flow path and the second flow path; and
a second side block blocking an other extended end among the extended ends at the two opposing sides of the first flow path and the second flow path.

6. The heat radiation device as claimed in claim 5,
further comprising a third flow path provided in any one of the first side block and the second side block and connecting the first flow path and the second flow path.

7. The heat radiation device as claimed in claim 6,
wherein a cross-sectional area of the third flow path is smaller than a cross-sectional area of the first flow path and a cross-sectional area of the second flow path.

8. The heat radiation device as claimed in claim 1, further comprising:
a first cover plate on one surface of the core plate to block the first flow path; and
a second cover plate on an other surface of the core plate to block the second flow path.

9. The heat radiation device as claimed in claim 1,
wherein the connection portion is an area where a portion of the core plate between the first flow path and the second flow path is removed.

10. The heat radiation device as claimed in claim 9,
wherein the cross-sectional area of the connection portion is larger than the cross-sectional area of the first flow path and smaller than the cross-sectional area of the second flow path.

11. The heat radiation device as claimed in claim 1,
wherein a cross-sectional area of the first flow path is smaller than a cross-sectional area of the second flow path.

12. The heat radiation device as claimed in claim 3,
wherein the first connection portion extends from the one end of the one direction of the core plate to the other end of the one direction, and
the second connection portion extends from the other end of the one direction of the core plate to the one end of the one direction.

13. The heat radiation device as claimed in claim 2,
wherein the connection portion is provided as a plurality of holes penetrating the core plate between the first flow path and the second flow path.

14. The heat radiation device as claimed in claim 13,
wherein the plurality of holes are provided in the thickness direction of the core plate and the one direction.

15. The heat radiation device as claimed in claim 14,
wherein at least one or more among the plurality of holes have a diameter different from a diameter of another hole among the plurality of holes.

16. The heat radiation device as claimed in claim 15,
wherein a diameter of each of the holes provided at a central portion among the plurality of holes is larger than a diameter of each of the holes provided at a peripheral portion among the plurality of holes.

17. The heat radiation device as claimed in claim 3,
further comprising a guide portion extending from the connection portion to the flow direction of the refrigerant.

18. The heat radiation device as claimed in claim 17,
wherein the guide portion comprises a plurality of guide portions,
the plurality of guide portions each comprise a first guide portion and a second guide portion,
the first guide portion extends from the first connection portion, and
the second guide portion extends from the second connection portion.

19. The heat radiation device as claimed in claim 18,
wherein the first guide portion extends from the first connection portion toward the second flow path, and
the second guide portion extends from the second connection portion toward the first flow path.

20. The heat radiation device as claimed in claim 19,
wherein the first guide portion extends toward the one end of the one direction of the core plate, and
the second guide portion extends toward the other end of the one direction of the core plate.

21. An electronic device comprising:
a heat radiation device comprising:
a core plate;
a first flow path in which one surface of the core plate is recessed in a thickness direction of the core plate to form a path in which refrigerant flows through;
a second flow path in which an other surface opposite to the one surface of the core plate is recessed in the thickness direction of the core plate to form a path in which the refrigerant flows through; and
a connection portion connecting the first flow path and the second flow path.

22. The electronic device as claimed in claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
